(19) United States
(12) Patent Application Publication
(10) Pub. No.: US 2014/0233595 A1
(43) Pub. Date: Aug. 21, 2014

(54) Vertical Cavity Surface Emitting Laser With An Integrated Protection Diode

(71) Applicant: AVAGO TECHNOLOGIES GENERAL IP (SINGAPORE) PTE. LTD., Singapore (SG)

(72) Inventor: Ramana Murty, Sunnyvale, CA (US)

(73) Assignee: Avago Technologies General IP (Singapore) Pte. Ltd., Singapore (SG)

(21) Appl. No.: 13/768,780

(22) Filed: Feb. 15, 2013

(51) Int. Cl. H01S 5/026; H01L 33/60

(52) U.S. Cl. CPC H01S 5/026; H01L 33/60
USPC 372/38.09; 438/29

(57) ABSTRACT

A semiconductor device includes a vertical cavity surface emitting laser (VCSEL) with an integrated protection diode arranged between the VCSEL and an emitting surface. By locating the protection diode above the VCSEL, a minimal increase in substrate area is consumed to protect the VCSEL from electrostatic discharge events. A relatively small capacitance introduced by the protection diode, is controllably adjusted by one of the radial size of the protection diode and the thickness of the intrinsic layer therein. The relatively small capacitance introduced by the protection diode enables the VCSEL to operate at data rates above 10 Gb/s.

### BACKGROUND

Vertical cavity surface emitting lasers (VCSELs) are widely used as light sources for optical interconnect devices, storage area networks, and sensors. In order to enable VCSELs to operate at increasingly higher speeds, or data rates, the aperture sizes must be made increasingly smaller. Decreasing the size of the aperture, however, makes the VCSEL increasingly susceptible to electrostatic discharge (ESD) damage. Failure from an ESD event is a frequent cause of customer returns of VCSELs.

VCSELs have a p-intrinsic-n (PIN) structure and the damage threshold for ESD is asymmetric, i.e., an ESD pulse traveling in the reverse-bias direction is more damaging than an ESD pulse traveling in the forward-bias direction. The ESD damage threshold for VCSELs is commonly characterized by models such as the human body model (HBM) and the machine model (MM). For a VCSEL aperture diameter in the range of 5-10 micrometers (microns), the HBM damage threshold voltage is typically in the range of 100 to 200 volts (V) and the MM damage threshold voltage is typically under 50 V.

It is known to integrate a protection diode with a laser diode in a semiconductor device. For example, U.S. Pat. Nos. 6,185,240, 7,508,047 and 7,693,201 each disclose semiconductor devices in which a laser diode and a protection diode are integrated together in a semiconductor material. One of the problems associated with integrating the protection diode together with the laser diode in the same semiconductor is that the inclusion of the protection diode introduces capacitance, which limits the operating speed of the laser diode. The capacitance C_{d} of the protection diode can be expressed as:

C_{d}=εA/D, (Equation 1)

where, ε is the permittivity of the semiconductor material, A is the area of protection diode, and D is the width of depletion region of the protection diode. Decreasing the area, A, or increasing the width, D, of the depletion region will decrease the capacitance, C_{d}, of the protection diode. Decreasing area A to reduce C_{d} is not desirable because a small area A leads to a high thermal resistance and high current density. The high thermal resistance will lead to rapid temperature rise during an ESD event and result in a low damage threshold. On the other hand, increasing the area, A, of the protection diode increases the damage threshold voltage of the laser diode, but also increases the amount of capacitance that is introduced by the protection diode, which limits the operating speed, or the data rate that can be supported by the laser diode.

For example, U.S. Pat. No. 7,508,047 shows a Zener diode that is placed below the VCSEL. In the illustrated embodiment, the area of the Zener diode is larger than the area of the VCSEL aperture and the depletion layer of the p⁺/n⁺ junction is relatively thin. These two factors result in a large capacitance that protects the VCSEL but renders the combination device unsuitable for signal operation above about 1 Gb/s.

The most common configuration of a VCSEL is a conducting n-type substrate with an n-type distributed Bragg reflector (DBR), an active region (intrinsic layer), and a p-type DBR sequentially grown on it. Although the design described in U.S. Pat. No. 6,185,240 can be configured such that C_{d} is relatively small; the design cannot be used in the common VCSEL configuration described above because the cathode (n-side) of the VCSEL and diode are always connected through the substrate. Consequently, the substrate cannot be a conducting substrate.

### SUMMARY

An improved VCSEL with an integrated protection diode (IPD) consistent with the present invention is a two-terminal semiconductor device. The VCSEL with an IPD uses a p-i-n arrangement of semiconductor materials to enable the protective diode between the aperture of the VCSEL and the emitting surface. The damage threshold for electro-static discharge events with the human body model are increased from 100-200 V to nearly 1 kV. The p-i-n arrangement minimizes diode capacitance to enable operation of the VCSEL at data rates in excess of 10 Gb/s. The VCSEL portion of the improved VCSEL with an IPD can be fabricated on both conducting n-type or p-type substrates and semi-insulating substrates. In addition, the VCSEL portion of the improved VCSEL with an IPD can be modulated with an anode drive signal (i.e., coupling a data signal on the p-side of the device), a cathode drive signal (i.e., coupling a data signal on the n-side of the device) or differentially. By arranging the protection diode above (or adjacent) to the VCSEL, the resulting device reduces the area required to produce a suitably protected VCSEL capable of producing an optical signal at high data rates.

An embodiment of the present invention relates to a two-terminal semiconductor device including a substrate, a first layer of a semiconductor material, a VCSEL, a second layer of a semiconductor material and a protection diode. The substrate has the first layer of a semiconductor material disposed on an upper surface. The VCSEL is disposed on an upper surface of the first layer of semiconductor material. The VCSEL is formed by a stacked pair of distributed Bragg reflectors arranged both below and above an active region. The VCSEL is further configured with an oxide layer that defines an aperture within the device. The second layer of a semiconductor material is arranged between the VCSEL and the protection diode. The protection diode is implemented using a set of stacked layers in a p-i-n arrangement. An ohmic p-type contact pad and an ohmic n-type contact pad are arranged in contact with both the VCSEL and the protection diode to form the terminals of the semiconductor device.

In an exemplary embodiment, a method for providing electrostatic discharge protection in a semiconductor device is disclosed. The method includes the steps of providing a substrate with an upper surface, forming at least one layer of semiconductor material on the upper surface of the substrate, forming a vertical cavity surface emitting laser disposed on the at least one layer of semiconductor material, the vertical cavity surface emitting laser having a first distributed Bragg reflector formed in a first set of layers, an intrinsic layer containing a light-emitting material disposed on top of the first plurality of layers, a second distributed Bragg reflector formed in a second set of layers, the vertical cavity surface emitting laser having an oxide layer proximal to the intrinsic layer arranged in the second set of layers, the oxide layer defining an aperture, forming a second layer of semiconductor material disposed on the second set of layers, forming a protection diode that in operation protects the vertical cavity surface emitting laser from electrostatic discharge events, the protection diode disposed on the second layer of semiconductor material located above the aperture, the protection diode having an intrinsic layer above a n-type layer and below a p++ type semiconductor material, forming an ohmic p-type contact pad in contact with the vertical cavity surface emitting laser and the protection diode, and forming an ohmic n-type contact pad in contact with the vertical cavity surface emitting laser and protection diode.

Other systems, methods, features, and advantages will be or become apparent to one with skill in the art upon examination of the following figures and detailed description. It is intended that all such additional systems, methods, features, and advantages be included within this description, be within the scope of the specification, and be protected by the accompanying claims.

### BRIEF DESCRIPTION OF THE DRAWINGS

An improved VCSEL with an integrated protective diode and methods for manufacturing the same can be better understood with reference to the following drawings. The components in the drawings are not necessarily to scale, emphasis instead being placed upon clearly illustrating the principles of the present invention.

FIG. 1 illustrates a cross-sectional side view of a semiconductor device including a VCSEL and an integrated protective diode in accordance with an illustrative, or exemplary, embodiment.

FIG. 2 illustrates an equivalent circuit diagram of the semiconductor device of in FIG. 1.

FIG. 3 illustrates a cross-sectional side view of a semiconductor device in accordance with an illustrative or exemplary embodiment.

FIG. 4 illustrates a top plan view of the semiconductor device of FIG. 3.

FIG. 5 illustrates a flow diagram including an embodiment of a method for providing electrostatic discharge protection in a semiconductor device.

### DETAILED DESCRIPTION

The described issues with integrating a protection diode with a laser diode in a semiconductor device, while still being able to support data rates above 10 Gb/s, as exemplified in the state of the art, are addressed by integrating a protection diode between a VCSEL and an emitting surface of a semiconductor device. By arranging a reverse-biased protection diode in a region above an aperture of the VCSEL, the improved semiconductor device minimizes the area required to implement the protection diode. As will be explained below, the size of the protection diode and the thickness of the intrinsic layer therein can be modified to achieve a desired capacitance to strike a balance between protection from ESD events and the capability to support data rates in excess of about 10 Gb/s. The VCSEL can be fabricated on both conducting (n-type or p-type) substrates and semi-insulating substrates. It will be understood that the polarity of the protection diode will change with a change in polarity of the VCSEL. It will be further understood that the protection diode need not be precisely coaxial with the aperture. That is, the protection diode can be offset from the axis of the aperture of the VCSEL.

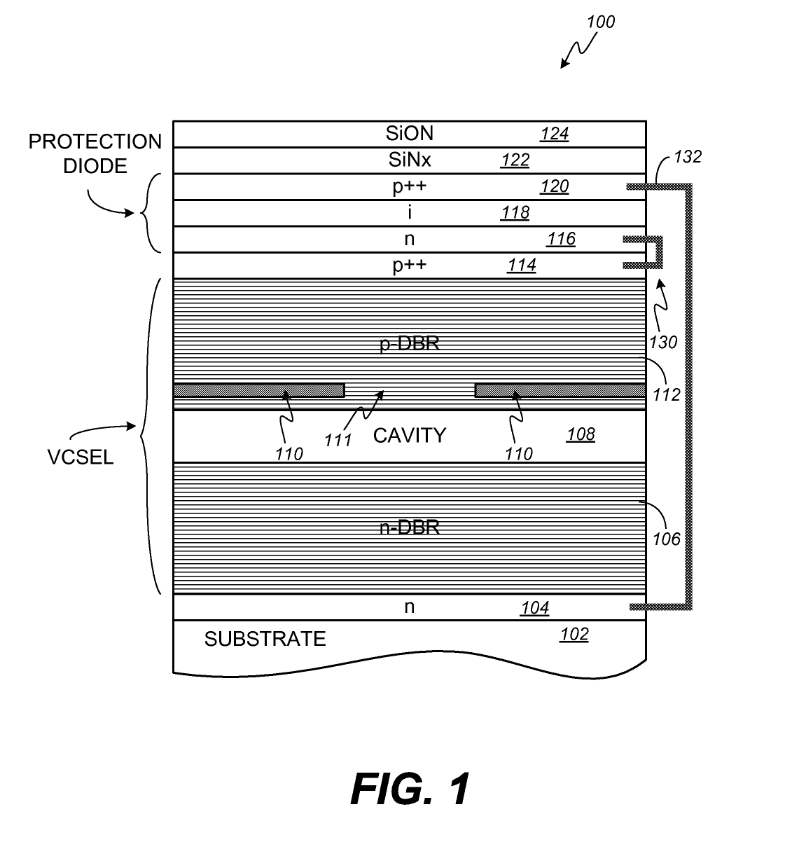

Illustrative, or exemplary, embodiments will now be described with reference to FIGS. 1-5, in which like reference numerals represent like features, elements or components.

FIG. 1 illustrates schematically a cross-sectional view of a semiconductor device 100. The semiconductor device 100 is fabricated as a series of material layers upon substrate 102. In the illustrated embodiment, the substrate 102 can be made from an electrically conducting material (e.g., an n-type material) or a semi-insulating material. The substrate 102 has a layer 104 of n-type material disposed thereon with a first or lower n-type distributed Bragg reflector (n-type DBR or n-DBR) 106 disposed above layer 104. A cavity 108 containing an active layer is disposed on n-DBR 106. A second or upper p-type DBR 112 (p-DBR) is disposed on the first intrinsic or active region 108. The cavity 108 may include one or more layers of photon emitting material. That is, the cavity emits light when current flows through the semiconductor device 100. The p-DBR 112 includes an oxide layer 110 that in operation confines current flow to an aperture 111. The oxide layer 110 can be produced by various methods including, for example, lateral oxidation of an aluminum gallium Arsenide (AlGaAs) layer with a high aluminum (Al) fraction, ion implantation or etching. As indicated in FIG. 1, the arrangement of the n-DBR 106 and p-DBR 112 about the cavity 108 forms a VCSEL.

A p++ layer 114 is disposed above the second or upper p-DBR 112. A protection diode is disposed on the p++ layer 114. A layer 116 of n-type material is disposed above the p++ layer 114. An intrinsic region or i-layer 118 is disposed above layer 116. A p++ layer 120 is disposed above the i-layer 118. As indicated in FIG. 1, the arrangement of the n-layer 116 and the p++ layer 120 about the intrinsic or i-layer 118 forms a protection diode.

Dielectric layers 122 and 124 are passivation layers deposited during device fabrication. In the illustrated embodiment the second dielectric layer 124 is made from SiON. Connection 130 conductively and physically couples p++ layer 114 to n-type layer 116. Similarly, connection 132 conductively and physically couples p++ layer 120 to n-type layer 104.

The protection diode provides a low impedance path for ESD pulses traveling in the reverse-bias direction of the VCSEL, while ESD pulses traveling in the forward-bias direction of the VCSEL pass mainly through the VCSEL. Thus, the protection diode protects the VCSEL from ESD events that can cause the greatest damage to the VCSEL, namely, ESD pulses traveling in the reverse-bias direction.

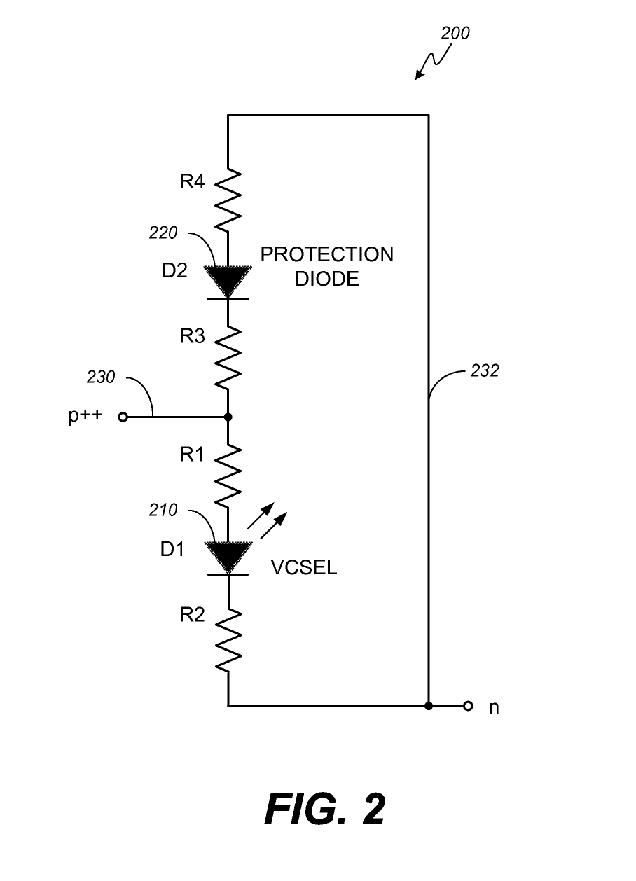

FIG. 2 illustrates an equivalent circuit diagram 200 for the semiconductor device 100 shown in FIG. 1. Diode D1 corresponds to the VCSEL 210. Diode D2 corresponds to the protection diode 220. A first resistor, R1, represents the upper or p-DBR 112 and the p-contact of the VCSEL 210. A second resistor, R2, represents the lower or n-DBR 106 and the n-contact of the VCSEL 210. A third resistor, R3, represents the n-contact of the protection diode 220. A fourth resistor, R4, represents the p-contact of the protection diode 220. Node 230 is the circuit equivalent of the connection 130 (FIG. 1). Similarly, node 232 is the circuit equivalent of connection 132 (FIG. 1).

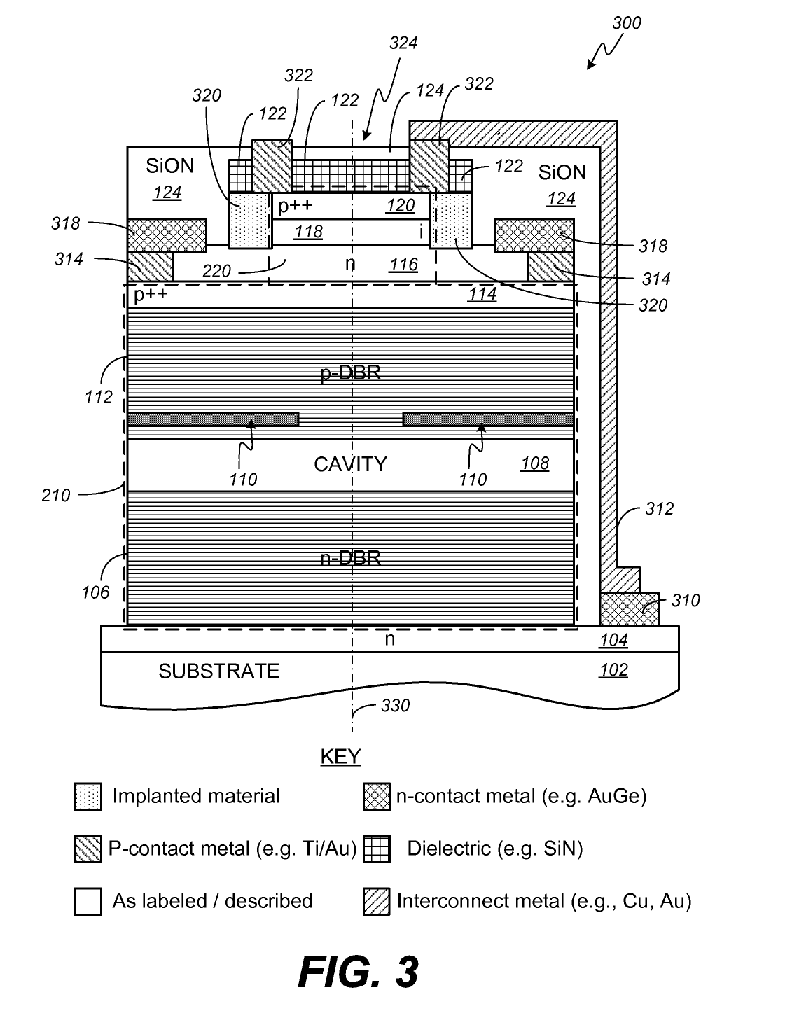

FIG. 3 illustrates a cross-sectional view of a semiconductor device 300. The example embodiment illustrated in FIG. 3 reveals additional detail as to the construction of the protection diode 220, internal conductive connections and interconnects or terminals of the semiconductor device 300. As indicated in FIG. 3, substrate 102 and layer 104 extend beyond the VCSEL 210 and the protection diode 220 to support other integrated circuit devices and connections (not shown). The n-DBR 106, cavity 108, p-DBR 112 and the p++ layer 114 are unchanged from the arrangement shown in FIG. 1.

As further shown in FIG. 3, an outer portion of the n-type layer 116 of the protection diode 220 may be etched or otherwise removed. The p-contact 314 to the VCSEL is made on the p++ layer 114 adjacent to the removed outer portion of the n-type layer 116. A region adjacent to the intrinsic layer 118 and the p++ layer 120 of the protection diode 220 is modified (etched and or implanted) to form a mesa 320. The mesa 320 limits or defines the area of i-layer 118 and the p++ layer 120 of the protection diode 220.

The n-contact 318 is deposited on the exposed portion of layer 116 such that it overlaps and electrically contacts p-contact 314. In this way, the p-contact 314 and n-contact 318 electrically couple the n-type layer 116 of the protection diode 220 with the p++ layer 114 of the VCSEL 210.

A first dielectric layer 122, which may be made from silicon nitride (SiN) is applied or otherwise provided above the p++ layer 120. A second dielectric layer 124 which may be silicon oxynitride (SiON) is disposed over exposed regions of the semiconductor to serve as a passivation layer. A portion of the layers 122 and 124, in registration above a portion of mesa 320 and p++ layer 120 of protection diode 220 is removed and replaced by p-contact 322, which may be a bilayer film of Ti/Au. As further indicated in FIG. 3, the p-contact 322 is coupled to n-contact 310 by interconnect metal 312, which may be titanium, gold, or other metals as desired.

The p-contact 314, the n-contact 318, mesa 320, and p-contact 322 are shown in FIG. 3 with left-side and right-side portions in the cross-section. While the illustrated embodiment contemplates coaxially arranged features about axis 330 (i.e., these elements are formed as open rings centered about axis 330), it should be understood that alternative configurations may be deployed, while still enabling a working device. For example, one or more of the n-contact 318, mesa 320, and p-contact 322 can be provided in the shape of a parallelogram with the corresponding element surrounding the axis 330.

Accordingly, it will be appreciated that the area of the protection diode can be precisely controlled by placement of the mesa 320. Moreover, it should be appreciated that the thickness of the intrinsic layer 118 of the protection diode 220 can be precisely controlled by monitoring epitaxial growth of the intrinsic layer 118 above the n-type layer 116. Accordingly, the capacitance introduced by the protection diode 220 can be controllably adjusted to enable the VCSEL 210 to operate at data rates in excess of about 10 Gb/s, while in turn providing sufficient protection against potentially catastrophic electro-static discharge events in the reverse-bias direction.

The p++ layer 120, intrinsic layer 118 and the n-type layer 116 of the protection diode 220 may modify the reflectance of the upper p-type DBR 112 of the VCSEL 210, and are taken into account in the VCSEL design. For example, the thicknesses of each of these layers may be made equal to a suitable multiple of the half-wavelength of the light emitted during operation of the VCSEL.

For operation of the VCSEL 210 at high data rates, the parasitic capacitance arising from the additional semiconductor junction between n-type layer 116 and the p++ layer 120 of the protection diode 220, as well as the parasitic capacitance arising from the interconnect 312 and an interconnect coupled to p-contact 314 (not shown), should be kept small. The internal metal connection provided by the diode n-contact 318 to VCSEL p-contact 314 contributes negligible capacitance and inductance. Interconnect 312, which couples the p++ layer 120 of the protection diode 220 to the n-contact of the VCSEL 210 is applied over the thick dielectric layer 124 and/or dielectric layer 122. Consequently, the interconnect 312 can be several microns wide and still contribute only a small amount of capacitance and inductance.

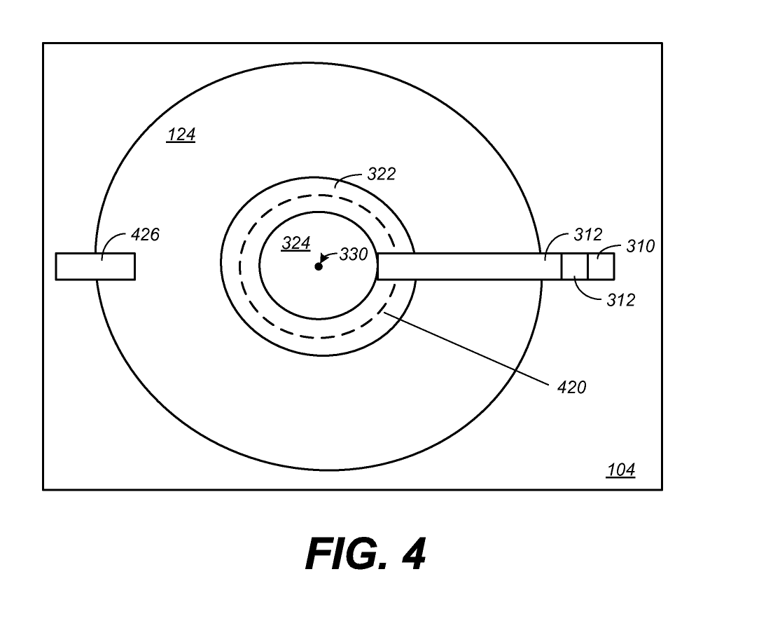

FIG. 4 illustrates a top plan view of the semiconductor device 300 of FIG. 3. As shown in FIG. 3, the semiconductor device 300 is generally arranged coaxially on axis 330 above the n-type layer 104. An emitting surface 324 is bounded by a p-contact 322. Interconnect 312 overlays both the dielectric layer 124 and p-contact 322 and further connects the p-contact 322 with the n-contact 310, which is just above the n-type layer 104. Interconnect 426 provides a conductive path for coupling the internal p-contact 314 of the semiconductor device 300 to external elements. Hidden line 420 represents the location of the junction of mesa 320 with the intrinsic layer 118 and the p++ layer 120 of the protection diode 220.

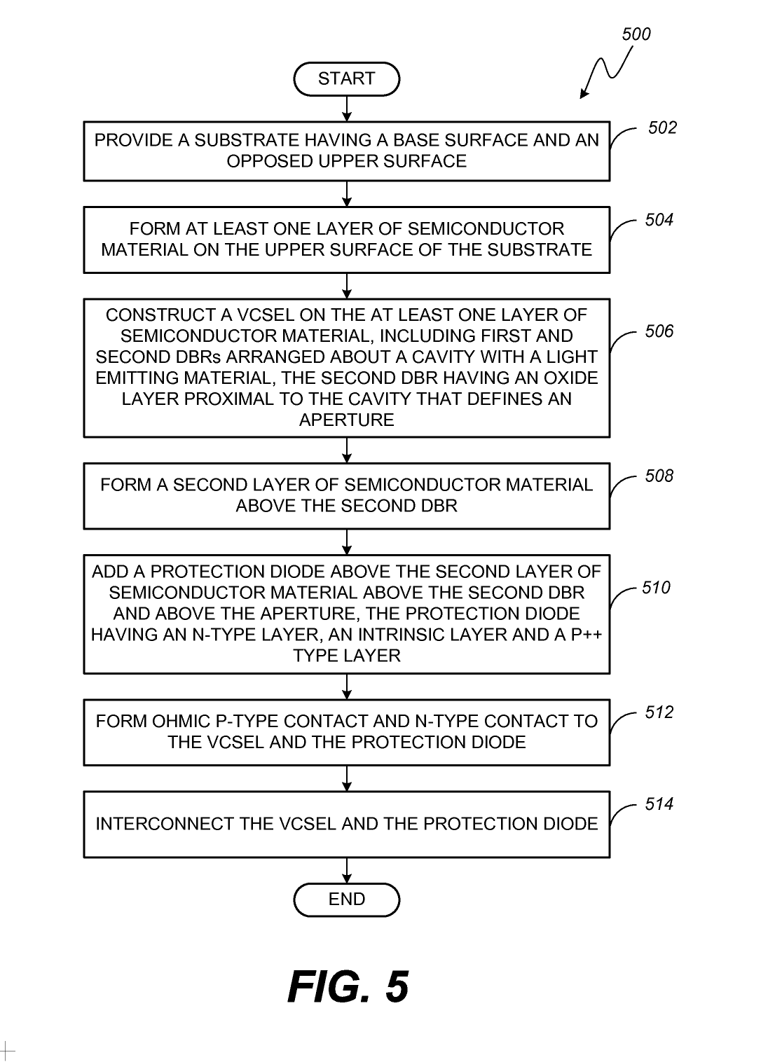

FIG. 5 illustrates a flow diagram including an embodiment of a method for providing electrostatic discharge protection in a semiconductor device. The method 500 begins with block 502 where a substrate with an upper surface is provided. In block 504, at least one layer of semiconductor material is formed on the upper surface of the substrate. In block 506, a vertical cavity surface emitting laser is disposed on the at least one layer of semiconductor material. As indicted in block 506, the vertical cavity surface emitting laser includes a first distributed Bragg reflector formed in a first set of layers, a cavity containing a light-emitting material disposed on top of the first plurality of layers, and a second distributed Bragg reflector formed in a second set of layers. As further indicated in block 506, the vertical cavity surface emitting laser also includes an oxide layer within the second set of layers and proximal to the cavity. As described above, the oxide layer defines an aperture. Thereafter, in block 508, a second layer of semiconductor material is disposed or formed on the second set of layers of the second DBR. In block 510, a protection diode that in operation protects the vertical cavity surface emitting laser from electrostatic discharge events is disposed on the second layer of semiconductor material above the aperture. As further indicated in block 510, the protection diode includes an intrinsic layer above an n-type layer and below a p++ type semiconductor material. In block 512, ohmic p-type and n-type contacts are formed to the vertical cavity surface emitting laser and the protection diode. In block 514, the VCSEL and diode are connected.

The invention is not limited with respect to the chemical elements or compounds that are used for the various layers of the semiconductor device 100 or the semiconductor device 300. Known semiconductor processes may be used to fabricate the example semiconductor devices, and a variety of materials may be used to make the same. An example of materials that may be used to make the semiconductor device 100 or the semiconductor device 300 is as follows: the substrate 102 is made of n-doped gallium arsenide (GaAs); the layer 104 is made up of n-doped GaAs; the lower or n-DBR 106 is made up of several layers of n-doped aluminum gallium arsenide (AlGaAs) having different percentages of Al or Ga to make them alternate between high and low refractive indices; the cavity 108 contains GaAs quantum wells that are un-doped or have a very low doping; the upper or p-DBR 112 is made up of several layers of p-doped AlGaAs having different percentages of Al or Ga to make them alternate between high and low refractive indices; the p++ layer 114 is made up of highly p-doped AlGaAs; n-type layer 116 is made from n-doped AlGaAs; the intrinsic layer 118 of the protection diode is made up of AlGaAs that is un-doped or that has a very low doping; the layer 120 is made up of highly p-doped GaAs; layer 122 is made of a dielectric material such as silicon nitride (SiN); and the layer 124 is made of a dielectric material such as silicon oxynitride (SiON).

While the described semiconductor devices are made primarily of GaAs related materials, other compounds may be used for the semiconductor device 100 or the semiconductor device 300. The compounds can be selected to have desired bandgap energies that enable desired light emission wavelengths to be produced. Examples of other suitable materials that may be used include, but are not limited to, aluminum gallium arsenide (AlGaAs), gallium phosphide (GaP), indium gallium phosphide (InGaP), gallium nitride (GaN), indium gallium arsenide (InGaAs), indium gallium arsenide nitride (InGaNAs), indium phosphide (InP), and gallium indium phosphide (GaInP). It should also be noted that layers that are designated in FIG. 1 as being of n-type may instead be of p-type, and vice versa. For example, if the substrate 102, layer 104 and the lower DBR 106 are made of p-type material, the upper DBR 112 and layer 114 will be made of n-type material and the layer 116 will be made of p-type material and the layer 120 will be made of n++ type material.

It should also be noted that the invention is not limited with respect to the manner in which the VCSEL modulation signal is applied to the VCSEL 210. For example, the modulation signal may be applied to the VCSEL 210 on the p side (i.e., anode drive), on the n side (i.e., cathode drive by replacing the n-type substrate with a semi-insulating substrate), or differentially (i.e., a differential signal applied across the p and n sides of the VCSEL 210.

It should be noted that the invention has been described with reference to illustrative embodiments and that the invention is not limited to these specific embodiments. Those skilled in the art will understand the manner in which modifications can be made to the illustrative embodiments and that all such modifications are within the scope of the invention. For example, while FIG. 1 shows a particular combination of layers, the semiconductor device 100 may include more layers or fewer layers than what is shown in FIG. 1. These and other modifications may be made to the embodiments described herein and all such modified embodiments are also within the scope of the invention, as defined by the claims.

What is claimed is:

1. A semiconductor device comprising:
a substrate having at least one layer of semiconductor material formed on an upper surface thereof;
a vertical cavity surface emitting laser disposed on the upper surface of the at least one layer of semiconductor material, the vertical cavity surface emitting laser having a first distributed Bragg reflector formed in a first set of layers, wherein at least one of the first set of layers is of an n-type material, a cavity containing a light-emitting material disposed on top of the first plurality of layers, a second distributed Bragg reflector formed in a second set of layers, and a first p++ layer disposed on the second set of layers, wherein at least one of the second set of layers is of a p-type material, the vertical cavity surface emitting laser having an oxide layer proximal to the intrinsic layer arranged in the second set of layers, the oxide layer defining an aperture;
a protection diode for protecting the vertical cavity surface emitting laser from electrostatic discharge events disposed on the first p++ layer located above the aperture, the protection diode having at least one layer of n-type semiconductor material disposed on the first p++ layer, an intrinsic layer disposed on the at least one layer of n-type semiconductor material, and a second p++ layer disposed on the intrinsic layer;
an ohmic p-type contact pad and an ohmic n-type contact pad in contact with the vertical cavity surface emitting laser and protection diode;
a first metal interconnect connecting the p-contact pad of the vertical cavity surface emitting laser with the n-contact of the protection diode; and
a second metal interconnect connecting the n-contact pad of the vertical cavity surface emitting laser with the p-contact of the protection diode.

2. The semiconductor device of claim 1, wherein the size of the protection diode is defined by implantation to achieve a desired capacitance.

3. The semiconductor device of claim 1, wherein a thickness of the second intrinsic layer is defined by epitaxy to achieve a desired capacitance.

4. The semiconductor device of claim 3, wherein the size of the protection diode as defined by implantation in conjunction with the thickness of the intrinsic layer are used to achieve a desired capacitance.

5. The semiconductor device of claim 1, wherein the protection diode is coaxially arranged above the aperture.

6. The semiconductor device of claim 1, wherein the substrate comprises a conducting material.

7. The semiconductor device of claim 1, wherein the substrate comprises a semi-insulating material.

8. The semiconductor device of claim 1, where the aperture confines current and is achieved by one of ion implantation, etching, and lateral oxidation.

9. The semiconductor device of claim 1, further comprising:
at least one layer of dielectric material disposed on the semiconductor device and electrically isolating the p-contact pad and n-contact pad from each other, wherein the intrinsic layer reduces a capacitance of the protection diode to allow the vertical cavity surface emitting laser to operate at data rates above 10 Gb/s.

10. A semiconductor device comprising:
a substrate having at least one layer of semiconductor material formed on an upper surface thereof;
a vertical cavity surface emitting laser disposed on the upper surface of the at least one layer of semiconductor material, the vertical cavity surface emitting laser having a first distributed Bragg reflector formed in a first set of layers, wherein at least one of the first set of layers is of a p-type material, a cavity containing a light-emitting material disposed on top of the first plurality of layers, a second distributed Bragg reflector formed in a second set of layers, and a first n++ layer disposed on the second set of layers, wherein at least one of the second set of layers is of a n-type material, the vertical cavity surface emitting laser having an oxide layer proximal to the intrinsic layer arranged in the second set of layers the oxide layer defining an aperture;
a protection diode for protecting the vertical cavity surface emitting laser from electrostatic discharge events disposed on the first n++ layer located above the aperture, the protection diode having at least one layer of p++ type semiconductor material disposed on the first n++ layer, an intrinsic layer disposed on the at least one layer of p++ type semiconductor material, and a second n++ layer disposed on the second intrinsic layer;
an ohmic p-type contact pad and an ohmic n-type contact pad in contact with the vertical cavity surface emitting laser and protection diode;
a first metal interconnect connecting the n-contact pad of the vertical cavity surface emitting laser with the p-contact of the protection diode; and
a second metal interconnect connecting the p-contact pad of the vertical cavity surface emitting laser with the n-contact of the protection diode.

11. The semiconductor device of claim 10, wherein at least one of size of the protection diode is defined by implantation and a thickness of the second intrinsic layer is controllably modified to achieve a desired capacitance.

12. The semiconductor device of claim 10, wherein the protection diode is coaxially arranged above the aperture.

13. The semiconductor device of claim 10, wherein the substrate comprises a conducting material.

14. The semiconductor device of claim 10, wherein the substrate comprises a semi-insulating material.

15. The semiconductor device of claim 10, where the aperture defined by the oxide layer is achieved by one of ion implantation, etching, and lateral oxidation.

16. The semiconductor device of claim 10, further comprising:
at least one layer of dielectric material disposed on the semiconductor device and electrically isolating the p-contact pad and n-contact pad from each other, wherein the intrinsic layer reduces a capacitance of the protection diode to allow the vertical cavity surface emitting laser to operate at data rates above 10 Gb/s.

17. A method for providing electrostatic discharge protection in a semiconductor device, the method comprising:
providing a substrate with an upper surface;
forming at least one layer of semiconductor material on the upper surface of the substrate;
forming a vertical cavity surface emitting laser disposed on the at least one layer of semiconductor material, the vertical cavity surface emitting laser having a first distributed Bragg reflector formed in a first set of layers, an intrinsic layer containing a light-emitting material disposed on top of the first plurality of layers, a second distributed Bragg reflector formed in a second set of layers, the vertical cavity surface emitting laser having an oxide layer proximal to the intrinsic layer arranged in the second set of layers, the oxide layer defining an aperture;
forming a second layer of semiconductor material disposed on the second set of layers; and
forming a protection diode that in operation protects the vertical cavity surface emitting laser from electrostatic discharge events, the protection diode disposed on the second layer of semiconductor material located above the aperture, the protection diode having an intrinsic layer above a n-type layer and below a p++ type semiconductor material;
forming an ohmic p-type contact pad in contact with the vertical cavity surface emitting laser and the protection diode; and
forming an ohmic n-type contact pad in contact with the vertical cavity surface emitting laser and protection diode.

18. The method of claim 17, wherein the capacitance of the protection diode is controllably adjusted by one of the size of the protection diode and the thickness of the second intrinsic layer.

19. The method of claim 18, wherein the size of the protection diode is limited by a mesa formed by implantation.

20. The method of claim 17, wherein the aperture defined by the oxide layer is achieved by one of ion implantation, etching, and lateral oxidation.
